(19) United States
(12) Patent Application Publication
(10) Pub. No.: US 2025/0322882 A1
(43) Pub. Date: Oct. 16, 2025

(54) SUBBLOCK-DEPENDENT WORD LINE RAMP RATES FOR A MEMORY SYSTEM

(71) Applicant: Micron Technology, Inc., Boise, ID (US)

(72) Inventors: Yu-Chung Lien, San Jose, CA (US); Zhenming Zhou, San Jose, CA (US)

(21) Appl. No.: 19/087,224

(22) Filed: Mar. 21, 2025

Related U.S. Application Data
(60) Provisional application No. 63/632,965, filed on Apr. 11, 2024.

(51) Int. Cl. G11C 16/10; G11C 16/08; G11C 16/12

(52) U.S. Cl. CPC G11C 16/102; G11C 16/08; G11C 16/12

(57) ABSTRACT

Methods, systems, and devices for subblock-dependent word line ramp rates are described. A memory device may select, for writing a first set of data and a second set of data, a block of memory cells that share a word line. The memory device may apply, via the word line as part of a first write operation to write the first set of data, a first voltage pulse having a first ramp rate to a first subblock having a first position within the block. And the memory device may apply, via the word line as part of a second write operation to write the second set of data, a second voltage pulse having a second ramp rate to a second subblock having a second position within the block.

### CROSS REFERENCE

The present Application for Patent claims priority to U.S. Patent Application No. 63/632,965 by Lien et al., entitled “SUBBLOCK-DEPENDENT WORD LINE RAMP RATES FOR A MEMORY SYSTEM,” filed Apr. 11, 2024, which is assigned to the assignee hereof, and which is expressly incorporated by reference in its entirety herein.

### TECHNICAL FIELD

The following relates to one or more systems for memory, including subblock-dependent word line ramp rates for a memory system.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 shows an example of a system that supports subblock-dependent word line ramp rates for a memory system in accordance with examples as disclosed herein.

FIG. 2 shows an example of a memory device that supports subblock-dependent word line ramp rates in accordance with examples as disclosed herein.

FIG. 3 shows an example of a memory block that supports subblock-dependent word line ramp rates for a memory system in accordance with examples as disclosed herein.

FIG. 4 shows examples of voltage pulses that support subblock-dependent word line ramp rates for a memory system in accordance with examples as disclosed herein.

FIG. 5 shows a block diagram of a memory system that supports subblock-dependent word line ramp rates in accordance with examples as disclosed herein.

FIGS. 6 and 7 show flowcharts illustrating a method or methods that support subblock-dependent word line ramp rates for a memory system in accordance with examples as disclosed herein.

### DETAILED DESCRIPTION

A memory device may include stacked tiers of memory cells and each tier of memory cells may be divided into one or more blocks. A block may be subdivided into subblocks to allow subblock-level control of the memory cells in the block. Due to manufacturing limitations and scaling constraints, one or more inner subblocks of a memory block may have thinner films (e.g., the tier material surrounding the memory cells may be thinner) than the one or more outer subblocks. For example, the thickness of the tier material may progressively decrease closer to the center of the block. Memory cells surrounded by or otherwise associated with thinner tier material may have reduced reliability and endurance relative to memory cells surrounded by or otherwise associated with thicker tier material, and thus inner subblocks may have reduced reliability and endurance relative to outer subblocks. To decrease latency of the memory device, it may be desirable to use programming pulses with relatively fast ramp rates. However, the performance issues of the inner subblocks (e.g., reduced reliability, reduced endurance) may be exacerbated by programming pulses with the relatively fast ramp rates.

According to the techniques described herein, the reliability and endurance of subblocks within a block may be balanced by applying programming pulses with different ramp rates to the various subblocks in different relative positions. For example, inner subblocks (e.g., inner toward the center compared to one or more other subblocks) may be subject to applied programming pulses with word line voltage pulses that have slower rates than the word line voltage pulses applied to outer subblocks (e.g., outer away from the center compared to one or more other subblocks). Use of a slower ramp rate for inner subblocks may increase the reliability and endurance of the inner subblocks (e.g., compared to techniques that use the faster ramp rate for all subblocks) whereas use of a faster ramp rate for outer subblocks may reduce the average programming latency for the block (e.g., compared to techniques that use the slower ramp rate for all subblocks). In some examples, inner subblocks (e.g., inner toward the center compared to one or more other intermediate and outer subblocks) may be subject to applied programming pulses with word line voltage pulses that have slower rates than the word line voltage pulses applied to intermediate subblocks (e.g., outer away from the center compared to one or more other inner subblocks) and outer subblocks (e.g., outer away from the center compared to one or more other inner subblocks and one or more intermediate subblocks). Use of a slower ramp rate for inner subblocks may increase the reliability and endurance of the inner subblocks (e.g., compared to techniques that use the faster ramp rate for all subblocks) whereas use of a faster ramp rate for intermediate subblocks and an even faster ramp rate for the outermost subblocks may reduce the average programming latency for the block (e.g., compared to techniques that use the slower ramp rate for all subblocks).

In addition to applicability in memory systems as described herein, techniques for subblock-dependent programming ramp rates may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving memory access speeds (without sacrificing reliability or endurance), which may decrease processing or latency times, improve response times, or otherwise improve user experience, among other benefits.

In addition to applicability in memory systems as described herein, techniques for subblock-dependent programming ramp rates may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by improving the endurance of memory cells, which may extend the life of electronic devices and thereby reduce electronic waste), among other benefits.

Features of the disclosure are illustrated and described in the context of systems, devices, and circuits. Features of the disclosure are further illustrated and described in the context of memory devices, memory blocks, timing diagrams, and flowcharts.

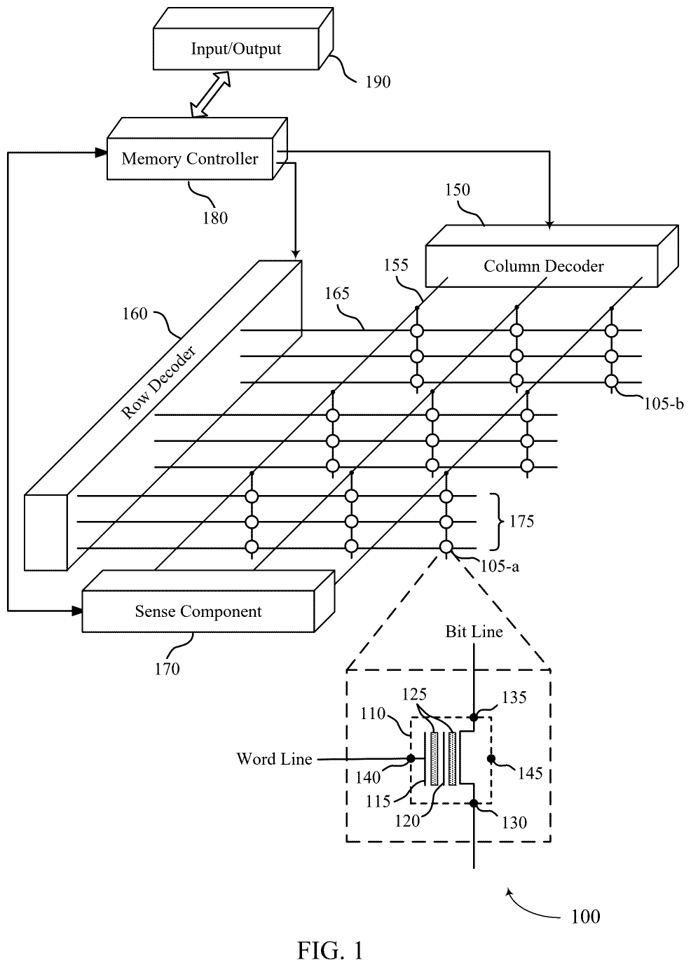

FIG. 1 shows an example of a memory device 100 that supports subblock-dependent word line ramp rates in accordance with examples as disclosed herein. FIG. 1 is an illustrative representation of various components and features of the memory device 100. As such, the components and features of the memory device 100 are shown to illustrate functional interrelationships, and not necessarily physical positions within the memory device 100. Further, although some elements included in FIG. 1 are labeled with a numeric indicator, some other corresponding elements are not labeled, even though they are the same or would be understood to be similar, in an effort to increase visibility and clarity of the depicted features.

The memory device 100 may include one or more memory cells 105, such as memory cell 105-a and memory cell 105-b. In some examples, a memory cell 105 may be a NAND memory cell, such as in the blow-up diagram of memory cell 105-a. Each memory cell 105 may be programmed to store a logic value representing one or more bits of information. In some examples, a single memory cell 105—such as a memory cell 105 configured as a single-level cell (SLC)—may be programmed to one of two supported states and thus may store one bit of information at a time (e.g., a logic 0 or a logic 1). In some other examples, a single memory cell 105—such a memory cell 105 configured as a multi-level cell (MLC), a tri-level cell (TLC), a quad-level cell (QLC), or other type of multiple-level memory cell 105—may be programmed to one state of more than two supported states and thus may store more than one bit of information at a time. In some cases, a multiple-level memory cell 105 (e.g., an MLC memory cell, a TLC memory cell, a QLC memory cell) may be physically different than an SLC cell. For example, a multiple-level memory cell 105 may use a different cell geometry or may be fabricated using different materials. In some examples, a multiple-level memory cell 105 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

In some NAND memory arrays, each memory cell 105 may be illustrated as a transistor that includes a charge trapping structure (e.g., a floating gate, a replacement gate, a dielectric material) for storing an amount of charge representative of a logic value. For example, the blow-up in FIG. 1 illustrates a NAND memory cell 105-a that includes a transistor 110 (e.g., a metal-oxide-semiconductor (MOS) transistor) that may be used to store a logic value. The transistor 110 may include a control gate 115 and a charge trapping structure 120 (e.g., a floating gate, a replacement gate), where the charge trapping structure 120 may, in some examples, be between two portions of dielectric material 125. The transistor 110 also may include a first node 130 (e.g., a source or drain) and a second node 135 (e.g., a drain or source). A logic value may be stored in transistor 110 by storing (e.g., writing) a quantity of electrons (e.g., an amount of charge) on the charge trapping structure 120. An amount of charge to be stored on the charge trapping structure 120 may depend on the logic value to be stored. The charge stored on the charge trapping structure 120 may affect the threshold voltage of the transistor 110, thereby affecting the amount of current that flows through the transistor 110 when the transistor 110 is activated (e.g., when a voltage is applied to the control gate 115, when the memory cell 105-a is read). In some examples, the charge trapping structure 120 may be an example of a floating gate or a replacement gate that may be part of a 2D NAND structure. For example, a 2D NAND array may include multiple control gates 115 and charge trapping structures 120 arranged around a single channel (e.g., a horizontal channel, a vertical channel, a columnar channel, a pillar channel).

A logic value stored in the transistor 110 may be sensed (e.g., as part of a read operation) by applying a voltage to the control gate 115 (e.g., to control node 140, via a word line 165) to activate the transistor 110 and measuring (e.g., detecting, sensing) an amount of current that flows through the first node 130 or the second node 135 (e.g., via a bit line 155). For example, a sense component 170 may determine whether an SLC memory cell 105 stores a logic 0 or a logic 1 in a binary manner (e.g., based on a presence or absence of a current through the memory cell 105 when a read voltage is applied to the control gate 115, based on whether the current is above or below a threshold current). For a multiple-level memory cell 105, a sense component 170 may determine a logic value stored in the memory cell 105 based on various intermediate threshold levels of current when a read voltage is applied to the control gate 115, or by applying different read voltages to the control gate and evaluating different resulting levels of current through the transistor 110, or various combinations thereof. In one example of a multiple-level architecture, a sense component 170 may determine the logic value of a TLC memory cell 105 based on eight different levels of current, or ranges of current, that define the eight potential logic values that could be stored by the TLC memory cell 105.

An SLC memory cell 105 may be written by applying one of two voltages (e.g., a voltage above a threshold or a voltage below a threshold) to the memory cell 105 to store, or not store, an electric charge on the charge trapping structure 120 and thereby cause the memory cell 105 to store one of two possible logic values. For example, when a first voltage is applied to the control node 140 (e.g., via a word line 165) relative to a bulk node 145 (e.g., a body node) for the transistor 110 (e.g., when the control node 140 is at a higher voltage than the bulk), electrons may tunnel into the charge trapping structure 120. Injection of electrons into the charge trapping structure 120 may be referred to as programming the memory cell 105 and may occur as part of a write operation. A programmed memory cell may, in some cases, be considered as storing a logic 0. When a second voltage is applied to the control node 140 (e.g., via the word line 165) relative to the bulk node 145 for the transistor 110 (e.g., when the control node 140 is at a lower voltage than the bulk node 145), electrons may leave the charge trapping structure 120. Removal of electrons from the charge trapping structure 120 may be referred to as erasing the memory cell 105 and may occur as part of an erase operation. An erased memory cell may, in some cases, be considered as storing a logic 1. In some cases, memory cells 105 may be programmed at a page level of granularity due to memory cells 105 of a page sharing a common word line 165, and memory cells 105 may be erased at a block level of granularity due to memory cells 105 of a block sharing commonly biased bulk nodes 145.

In contrast to writing an SLC memory cell 105, writing a multiple-level (e.g., MLC, TLC, or QLC) memory cell 105 may involve applying different voltages to the memory cell 105 (e.g., to the control node 140 or bulk node 145 thereof) at a finer level of granularity to more finely control the amount of charge stored on the charge trapping structure 120, thereby enabling a larger set of logic values to be represented. Thus, multiple-level memory cells 105 may provide greater density of storage relative to SLC memory cells 105 but may, in some cases, involve narrower read or write margins or greater complexities for supporting circuitry.

A charge-trapping NAND memory cell 105 may operate similarly to a floating-gate NAND memory cell 105 but, instead of or in addition to storing a charge on a charge trapping structure 120, a charge-trapping NAND memory cell 105 may store a charge representing a logic state in a dielectric material between the control gate 115 and a channel (e.g., a channel between a first node 130 and a second node 135). Thus, a charge-trapping NAND memory cell 105 may include a charge trapping structure 120, or may implement charge trapping functionality in one or more portions of dielectric material 125, among other configurations.

In some examples, each page of memory cells 105 may be connected to a corresponding word line 165, and each column of memory cells 105 may be connected to a corresponding bit line 155 (e.g., digit line). Thus, one memory cell 105 may be located at the intersection of a word line 165 and a bit line 155. This intersection may be referred to as an address of a memory cell 105. In some cases, word lines 165 and bit lines 155 may be substantially perpendicular to one another, and may be generically referred to as access lines or select lines.

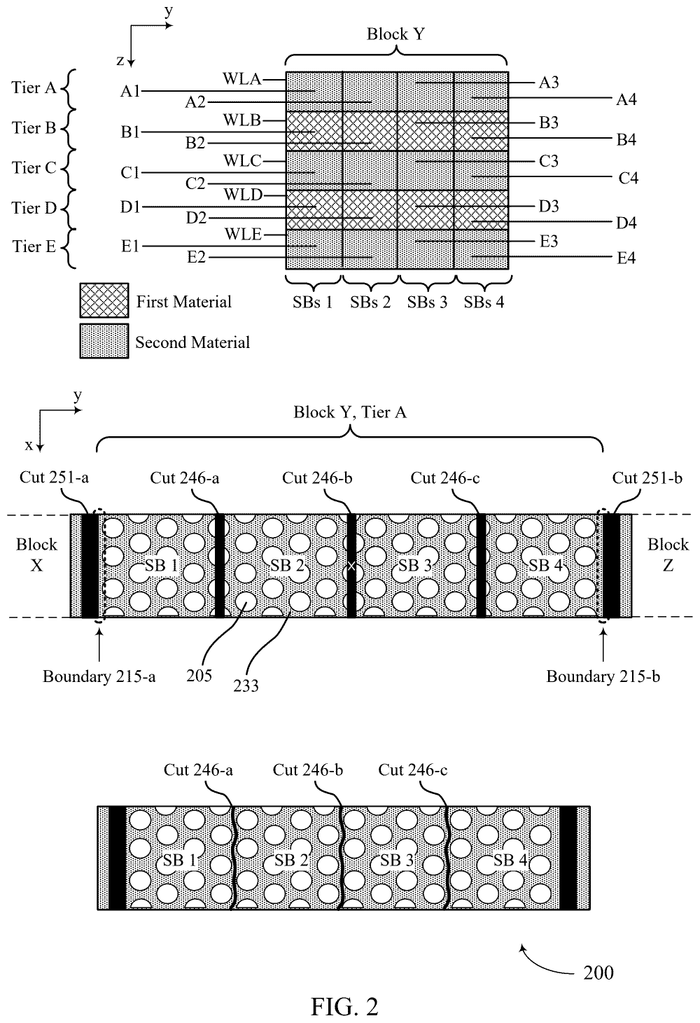

In some cases, a memory device 100 may include a three-dimensional (3D) memory array, where multiple two-dimensional (2D) memory arrays may be formed on top of one another. In some examples, such an arrangement may increase the quantity of memory cells 105 that may be fabricated on a single die or substrate as compared with 1D arrays, which, in turn, may reduce production costs, or increase the performance of the memory array, or both. In the example of FIG. 1, memory device 100 includes multiple levels (e.g., decks, layers, planes, tiers) of memory cells 105. The levels may, in some examples, be separated by an electrically insulating material. Each level may be aligned or positioned so that memory cells 105 may be aligned (e.g., exactly aligned, overlapping, or approximately aligned) with one another across each level, forming a memory cell stack 175. In some cases, memory cells aligned along a memory cell stack 175 may be referred to as a string of memory cells 105 (e.g., as described with reference to FIG. 2).

Accessing memory cells 105 may be controlled through a row decoder 160 and a column decoder 150. For example, the row decoder 160 may receive a row address from the memory controller 180 and activate an appropriate word line 165 based on the received row address. Similarly, the column decoder 150 may receive a column address from the memory controller 180 and activate an appropriate bit line 155. Thus, by activating one word line 165 and one bit line 155, one memory cell 105 may be accessed. As part of such accessing, a memory cell 105 may be read (e.g., sensed) by sense component 170. For example, the sense component 170 may be configured to determine the stored logic value of a memory cell 105 based on a signal generated by accessing the memory cell 105. The signal may include a current, a voltage, or both a current and a voltage on the bit line 155 for the memory cell 105 and may depend on the logic value stored by the memory cell 105. The sense component 170 may include various circuitry (e.g., transistors, amplifiers) configured to detect and amplify a signal (e.g., a current or voltage) on a bit line 155. The logic value of memory cell 105 as detected by the sense component 170 may be output via input/output component 190. In some cases, a sense component 170 may be a part of a column decoder 150 or a row decoder 160, or a sense component 170 may otherwise be connected to or in electronic communication with a column decoder 150 or a row decoder 160.

A memory cell 105 may be programmed or written by activating the relevant word line 165 and bit line 155 to enable a logic value (e.g., representing one or more bits of information) to be stored in the memory cell 105. A column decoder 150 or a row decoder 160 may accept data (e.g., from the input/output component 190) to be written to the memory cells 105. In the case of NAND memory, a memory cell 105 may be written by storing electrons in a charge trapping structure or an insulating layer.

A memory controller 180 may control the operation (e.g., read, write, re-write, refresh) of memory cells 105 through the various components (e.g., row decoder 160, column decoder 150, sense component 170). In some cases, one or more of a row decoder 160, a column decoder 150, and a sense component 170 may be co-located with a memory controller 180. A memory controller 180 may generate row and column address signals in order to activate a desired word line 165 and bit line 155. In some examples, a memory controller 180 may generate and control various voltages or currents used during the operation of memory device 100.

In some examples, the memory cells 105 of the memory device 100 may be in stacked tiers and the memory cells 105 in a given tier may share a word line 165. Within a tier, the memory cells 105 may be divided into blocks that include multiple smaller subblocks. Within a subblock, the memory cells 105 may be surrounded by a tier material (also referred to as tier film). Due to manufacturing limitations and the scale of the tiers, the tier material within inner subblocks of a block may be thinner relative to the outer subblocks of the block. Thus, the inner subblocks may have reduced performance (e.g., reliability, endurance) relative to the outer subblocks that may be exacerbated by faster (e.g., shorter) programming pulses. According to the techniques described herein, the performance of inner subblocks of a block may be increased or preserved (without sacrificing the access latency of outer subblocks of the block) by using different-duration programming pulses across the subblocks of the block. A programming pulse may also be referred to as a write pulse, a voltage pulse, or other suitable terminology.

FIG. 2 shows an example of a memory device that supports subblock-dependent word line ramp rates in accordance with examples as disclosed herein. The memory device 200 may be an example of a memory device 100 as described with reference to FIG. 1. The memory device 200 may include stacked tiers of memory cells labeled tier A through tier E. Although shown with five tiers the memory device 200 may include any quantity of tiers. A tier may include memory cells 205 arranged into sets of memory cells (e.g., blocks) and subsets of memory cells (e.g., subblocks). The memory cells may be portions of pillars that extend through the tiers in the z-direction. Although described with reference to blocks and subblocks, the variable-rate programming techniques may be implemented for any sets of memory cells divided into subsets of memory cells.

Although shown with a single block, a tier may include multiple blocks (e.g., sets of memory cells) that are separated by cuts through the tier. For example, as illustrated in the top-down view (middle figure) of block Y of tier A, block Y may be separated from block X by cut 251-a and may be separated from block Z by cut 251-b. The blocks of a tier may share (e.g., be coupled with) the same word line. For example, the blocks of tier A (e.g., block X, block Y, block Z) may each be coupled with word line A (WLA). Similarly, the blocks of tier B may each be coupled with word line B (WLB). And so on and so forth. Thus, there may one word line per tier. In other examples, there may be multiple word lines per tier.

Within a block, the subblocks (e.g., subsets of memory cells) may be separated by additional cuts. For example, as illustrated in the top-down view (middle figure) of block Y of tier A, subblock 1 (SB 1) may be separated from subblock 2 (SB 2) by cut 246-a (and vice versa). Subblock 2 may be separated from subblock 3 (SB 3) by cut 246-b (and vice versa). And subblock 3 may be separated from subblock 4 (SB 4) by cut 246-c. Although shown with four subblocks a block may include any quantity of subblocks.

The subblocks in a block of a tier may be coupled with respective selection transistors, also referred to as select gate drain (SGD) components, drain-end select gate components, or other suitable terminology. For example, referring to block Y of tier A: subblock 1 may be coupled with a first selection transistor via conductive line A1, subblock 2 may be coupled with a second selection transistor via conductive line A2, subblock 3 may be coupled with a second selection transistor via conductive line A3, and subblock 4 may be coupled with a second selection transistor via conductive line A4. The selection transistor for a subblock of a block may be configured to selectively couple that subblock with the word line for that block.

Accessing (e.g., writing) the memory cells 205 of a subblock of a block may involve selectively activating and deactivating the selection transistors of the block. For example, accessing the memory cells 205 of a subblock of a block may involve activating the word line (e.g., applying a voltage pulse on the word line) for the tier that includes the block, activating the selection transistor of the subblock (e.g., to couple the subblock with the word line), and deactivating the selection transistors for the other subblocks of the block (e.g., to isolate the other subblocks from the word line).

The cuts 251 may separate the blocks from other blocks in the tier or from the edges of the die. Thus, the cuts 251 may define the boundaries of the blocks. For example, block Y of tier A may have a first boundary 215-a (e.g., block boundary, block edge) defined by cut 251-a and may have a second boundary 215-b (e.g., block boundary, block edge) defined by cut 251-b. A cut 251 may be through the material 233 that surrounds the memory cells 205 and the cut 251 may extend through multiple tiers. The material 233 may be an oxide material or a metal material depending on the tier (e.g., the material 233 of the tiers may alternate). A cut may also be referred to as a slit, a trench, or other suitable terminology. A cut 251 may also be referred to as a block-defining cut or other suitable terminology.

The cuts 246 may separate subblocks from other subblocks in the block. Thus, the cuts 246 and the cuts 251 may define the boundaries of the subblocks. For example, referring to block Y of tier A, subblock 1 may have a first boundary (e.g., subblock boundary, subblock edge) defined by cut 251-a and may have a second boundary (e.g., subblock boundary, subblock edge) defined by cut 246-a. Subblock 2 may have a first boundary (e.g., subblock boundary, subblock edge) defined by cut 246-a and may have a second boundary (e.g., subblock boundary, subblock edge) defined by cut 246-b. Subblock 3 may have a first boundary (e.g., subblock boundary, subblock edge) defined by cut 246-b and may have a second boundary (e.g., subblock boundary, subblock edge) defined by cut 246-c. And subblock 4 may have a first boundary (e.g., subblock boundary, subblock edge) defined by cut 246-c and may have a second boundary (e.g., subblock boundary, subblock edge) defined by cut 251-b. A cut 246 may also be referred to as a subblock-defining cut or other suitable terminology.

Similar to the cuts 251, the cuts 246 may be through the material 233 that surrounds the memory cells 205. However, although the cuts 246 may extend through one or more, the cuts 246 may extend through fewer tiers than the cuts 251. For example, if the cuts 251 extend through a set of tiers, the cuts 246 may extend through a subset of the set of tiers. Additionally, the cuts 251 may be wider (e.g., in the y-direction) than the cuts 246 (e.g., due to the deeper depth of penetration). Thus, the cuts 251 that define the blocks may be deeper and wider than the cuts 246 that define the subblocks (e.g., the width of a cut 251 in the y-direction may be larger than the width of a cut 246).

In some examples (e.g., as shown in the middle figure), the cuts 246 may cut through a subset of the pillars (referred to as sacrificial pillars) in addition to cutting through the material 233 of the tier(s). But such a design may reduce the capacity of the memory device 200 (e.g., by destroying the functionality of the memory cells in the sacrificial pillars), increase the footprint of the memory device 200 (e.g., in the y-direction), or both, among other drawbacks. In other examples (e.g., as shown in the bottom figure), the cuts 246 may weave between the pillars of a tier so that the functionality of the memory cells in the tiers is preserved. Weaving the cuts 246 around the pillars of a tier may allow for increased capacity of the memory device 200, a decreased footprint of the memory device 200 (e.g., in the y-direction), or both, among other advantages. Additionally, or alternatively, the weaving the cuts 246 around the pillars may allow for de-integration of the selection transistors and thus may be referred to as a de-integrated SGD (d-SGD) design.

During manufacturing of the memory device 300, the material 233 of a block may be deposited via the cuts 251 (e.g., using the cuts 251 as conduits). For example, a block that is sandwiched between two tiers of a first material (e.g., an oxide material) may originally have a placeholder material (e.g., a nitride material) that is removed to form a cavity (e.g., void) through which the pillars traverse. After removal of the placeholder material, a second material (e.g., a metal material) may be deposited within the tier (e.g., surrounding the pillars) using the cuts 251 as conduits. But deposition techniques may not be capable of uniformly distributing the second material within the cavity (e.g., due to the close spacing of the tiers) which may result in the material 233 being progressively thinner (e.g., in the z-direction) closer to the center of the block (illustrated by the white X). The center of the block (in the y-direction) may also be referred to as the midpoint between the boundary 215-a and the boundary 215-b.

Thus, the inner subblocks (e.g., subblock 2 and subblock 3) of a block may have thinner tier material 233 than the outer subblocks (e.g., subblock 1 and subblock 4) of the block. Accordingly, the inner subblocks experience reduced reliability and endurance that is exacerbated by programming pulses with fast ramp rates (e.g., faster ramp rates may be associated with worsened reliability and endurance relative to slower ramp rates).

By varying the ramp rates of programming pulses applied to a block, the memory device 200 may improve or preserve the performance of the inner subblocks without increasing the access latency (e.g., writing latency) of the outer subblocks. For example, the memory device 200 may apply programming pulses with a first word line ramp rate (R1) to the inners subblocks (e.g., subblock 2 and subblock 3) to write memory cells in the inner subblocks. And the memory device 200 may apply programming pulses with a second word line ramp rate (R2) to the outer subblocks (e.g., subblock 1 and subblock 4) to write memory cells in the outer subblocks.

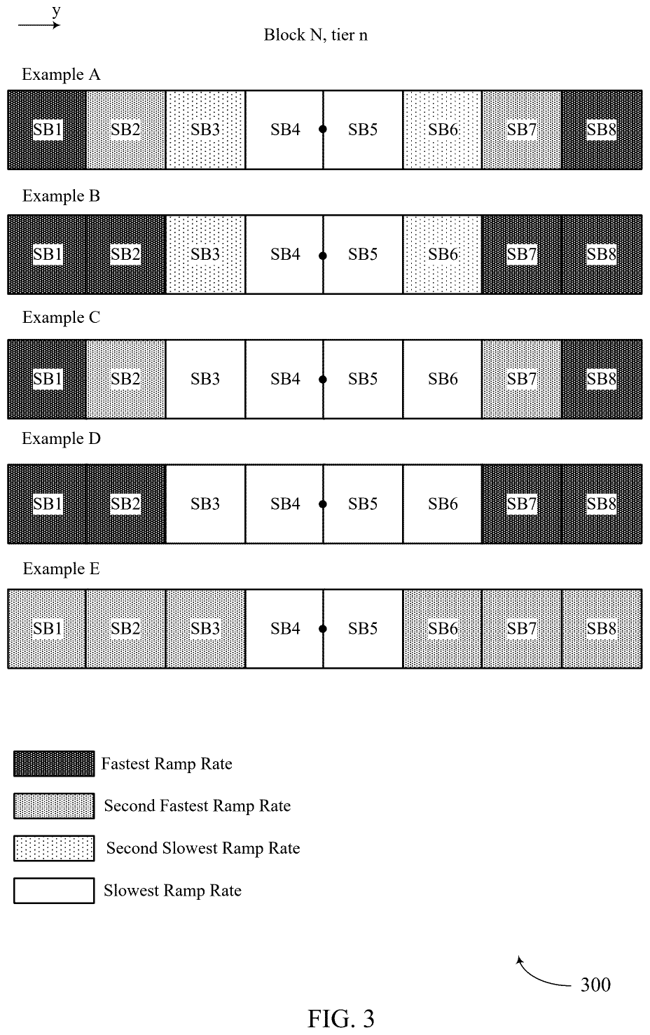

FIG. 3 shows an example of a memory block, block N, that supports subblock-dependent word line ramp rates in accordance with examples as disclosed herein. The block N may be a block of a memory device such as a memory device 100 or a memory device 200 as described with reference to FIGS. 1 and 2, respectively. So, the block N may be a block of a tier n within a stack of tiers of the memory device. The block N may include eight subblocks labeled SB1 through SB8. However, any quantity of subblocks is possible. The block N and the subblocks of the block N may be defined by cuts 251 and cuts 246 as described herein. The center or midpoint of the block N in the y-direction may be the denoted by the black X. Relative to the center of the block N, subblock 4 (SB 4) and subblock 5 (SB 5) may be the innermost subblocks and subblock 1 (SB1) and subblock 8 (SB 8) may be the outermost subblocks.

Due to manufacturing limitations and scaling constraints, the tier material of the block N may be progressively thinner closer to the center of the block N. To compensate for the thinner tier material of inner subblocks without sacrificing the access latency of the outer subblocks, the memory device may apply programming pulses with different word line ramp rates to the various subblocks of the block N. In general, programming pulses with faster ramp rates may be applied to subblocks with thicker tier material and programming pulses with slower ramp rates may be applied to subblocks with thinner tier material. Applying a programming pulse (e.g., voltage pulse) to a subblock may refer to applying the programming pulse to some or all of the memory cells of the subblock, for example, via the word line coupled with that subblock.

In some examples, the memory device may use four different ramp rates for the block N. For instance, in Example A, the memory device may apply the fastest ramp rate to subblocks 1 and 8 (SB 1, SB 8), may apply the second fastest ramp rate to subblocks 2 and 7 (SB 2, SB 7), may apply the second slowest ramp rate to subblocks 3 and 6 (SB 3, SB 6), and may apply the slowest ramp rate to subblocks 4 and 5 (SB 4, SB 5).

In some examples, the memory device may use three different ramp rates for the block N. For instance, in Example B, the memory device may apply the fastest ramp rate to subblocks 1, 2, 7, and 8 (SB 1, SB2, SB7, SB 8), may apply the second slowest ramp rate to subblocks 3 and 6 (SB 3, SB6), and may apply the slowest ramp rate to subblocks 4 and 5 (SB 4, SB 5). Alternatively, in Example C, the memory device may apply the fastest ramp rate to subblocks 1 and 8 (SB 1, SB 8), may apply the second fastest ramp rate to subblocks 2 and 7 (SB 2, SB 7), and may apply the slowest ramp rate to subblocks 3, 4, 5, and 6 (SB 3, SB 4, SB5, SB6).

In some examples, the memory device may use two different ramp rates for the block N. For instance, in Example D, the memory device may apply the fastest ramp rate to subblocks 1, 2, 7, and 8 (SB 1, SB2, SB7, SB 8) and may apply the slowest ramp rate to subblocks 3, 4, 5, and 6 (SB 3, SB 4, SB 5, SB 6). Alternatively, in Example E, the memory device may apply the second fastest ramp rate to subblocks 1, 2, 3, 6, 7, and 8 (SB 1, SB2, SB 3, SB 6, SB7, SB 8) and may apply the slowest ramp rate to subblocks 4 and 5 (SB 4, SB 5).

Thus, the memory device may apply programming pulses with different word line ramp rates to the subblocks of the block N. The described examples are for illustration and are not limiting in any way. Other combinations of ramp rates are contemplated and within the scope of the present disclosure.

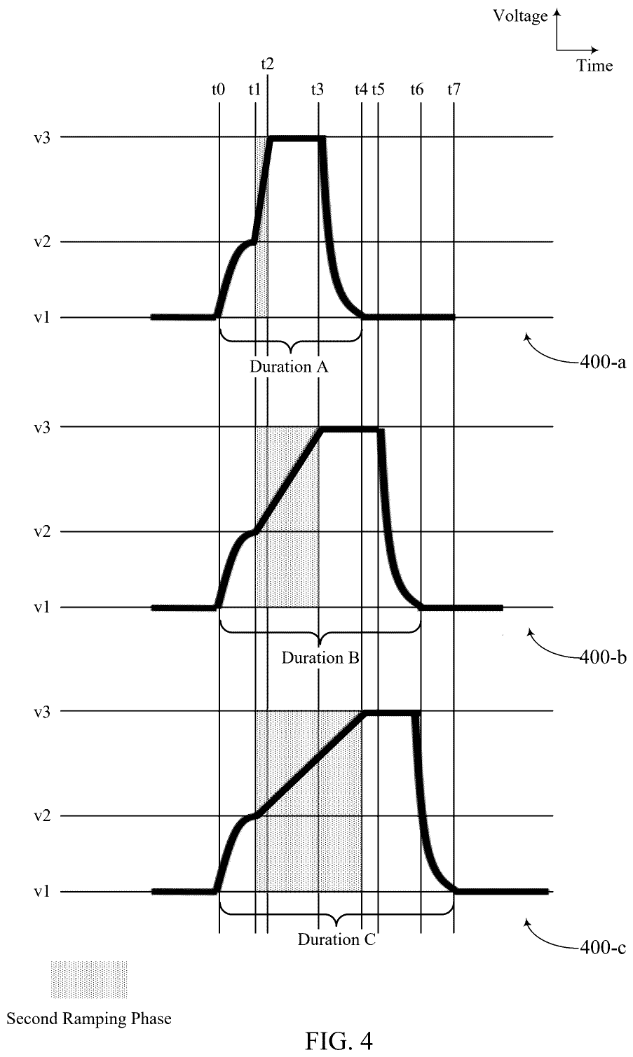

FIG. 4 shows an example of voltage pulses 400 that supports subblock-dependent word line ramp rates in accordance with examples as disclosed herein. FIG. 4 may illustrate the voltage amplitudes of voltage pulses 400 as a function of time. The voltage pulses 400 may be examples of programming pulses applied to memory cells of a block via a word line shared by (e.g., coupled with) the subblocks of the block. The block may be a block of a memory device such as a memory device 100 or a memory device 200 as described with reference to FIGS. 1 and 2, respectively.

The voltage pulses 400 may have different ramp rates and may be applied to different subblocks of the block. For example, voltage pulse 400-a may have the fastest ramp rate and may be applied to outer subblocks of the block, voltage pulse 400-b may have the intermediate ramp rate and may be applied to subblocks between the outer and inner subblocks of the block, and voltage pulse 400-c may have the slowest ramp rate and may be applied to the inner subblocks of the block. The voltage pulses may be used in the same type of write operation, such as an SLC write operation that writes two levels (e.g., one bit) per memory cell.

A voltage pulse 400 may have one or more phases. For example, a voltage pulse 400 may include a first ramping phase (e.g., in which the voltage pulse 400 is increased from voltage level v1 to voltage level v2), a second ramping phase (e.g., in which the voltage pulse 400 is increased from voltage level v2 to voltage level v3), a hold phase (e.g., in which the voltage pulse 400 is maintained at voltage level v3), and a ramp down phase (e.g., in which the voltage pulse 400 is decreased from voltage level v3 to voltage level v1).

The durations of the phases may be the substantially the same across the voltage pulses 400 except for the duration of the second ramping phase, which may differ across the voltage pulses 400 based on the respective ramp rates of the voltage pulses 400. Thus, the duration of voltage pulse 400-a (e.g., duration A) may be less than the duration of voltage pulse 400-b (e.g., duration B), which may be less than the duration of the voltage pulse 400-c (e.g., duration C), where the duration of a voltage pulse 400 is the duration between commencement of the first ramping phase for that voltage pulse and completion of the ramp down phase for that voltage pulse. Accordingly, the access latency (e.g., write latency) of memory cells written with the voltage pulse 400-a may be less than the access latency of memory cells written with voltage pulse 400-b, which may be less than the access latency of memory cells written with voltage pulse 400-c.

Application of a voltage pulse 400 to a memory cell may write a logic state (e.g., a logic 1) to that memory cell. In some examples, a voltage pulse 400 may include a verify phase after the ramp down phase of the voltage pulse 400. During the verify phase, the voltage pulse 400 may be temporarily increased to a fourth level (e.g., between voltage level v1 and voltage level v3) before decreasing to the voltage level v1. The verify phase may allow the memory device to verify that the logic state was successfully written to the memory cell.

During the first ramping phase, each voltage pulse 400 may increase (e.g., ramp) from a first level (e.g., v1) to a second level (e.g., v2) between time to and time t1. Thus, the ramp rates of the voltage pulses 400 may be the same for the first ramping phase of the voltage pulses 400 (e.g., the phase between time t0 and time t1).

However, the ramp rates of the voltage pulses 400 may differ in the second ramping phase in which the voltage pulses 400 increase (e.g., ramp) from the second level (e.g., v2) to the third level (e.g., v3). For instance, between time t1 and time t2 voltage pulse 400-a may increase from the second level (e.g., v2) to the third level (e.g., v3) at a first (e.g., fastest) ramp rate. Between time t1 and time t3 voltage pulse 400-b may increase from the second level to the third level at a second (e.g., intermediate) ramp rate. And between time t1 and time t4 voltage pulse 400-c may increase from the second level to the third level at a third (e.g., slowest) ramp rate. The second ramping phase for each voltage pulse 400 is shaded to illustrate the different durations of the second ramping phase across the voltage pulses.

During the hold phase, the voltage pulses 400 may be maintained at the third level (e.g., v3) for a threshold duration, which may be the same (e.g., equal) across the voltage pulses 400. For example, voltage pulse 400-a may be maintained at the third level between time t2 and time t3, voltage pulse 400-b may be maintained at the third level between time t3 and time t5, and voltage pulse 400-c may be maintained at the third level between time t4 and time t6. In some examples, the duration between time t2 and t3, the duration between time t3 and time t5, and the duration between time t4 and time t6 may be equal. Thus, the duration of the hold phase may be the same across voltage pulses 400 even though the hold phase may be offset (e.g., start at different times relative to time t0) between the voltage pulses 400.

During ramp down phase, the voltage pulses 400 may decrease from the third level (e.g., v3) to the first level (e.g., v1). For example, voltage pulse 400-a may be decreased from the third level to the first level between time t3 and time t4, voltage pulse 400-b may be decreased from the third level to the first level between time t5 and time t6, and voltage pulse 400-c may be decreased from the third level to the first level between time t6 and time t7. In some examples, the duration between time t3 and t4, the duration between time t5 and time t6, and the duration between time t6 and time t7 may be equal. Thus, the duration of the ramp down phase may be the same across voltage pulses 400 even though the ramp down phase may be offset (e.g., start at different times relative to time t0) between the voltage pulses 400.

Thus, voltage pulses 400 with different durations and ramp rates may be applied to different subblocks of a block.

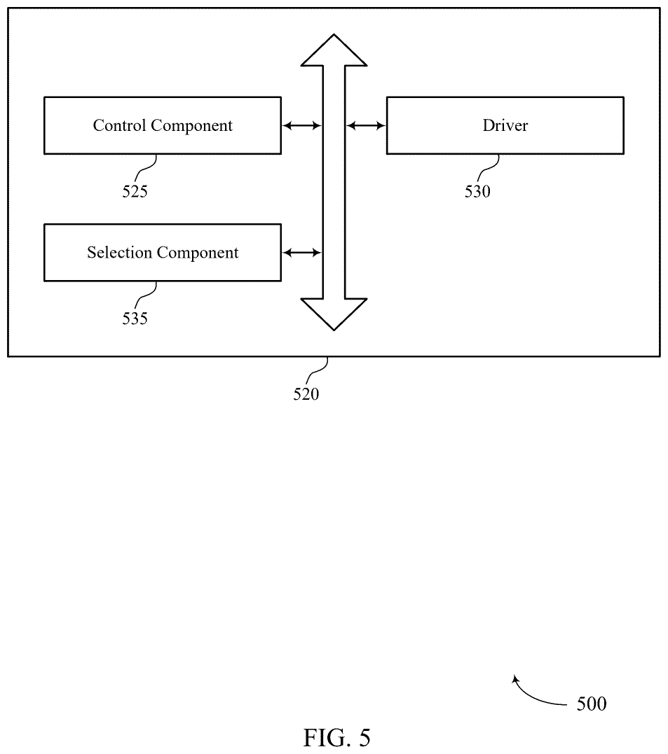

FIG. 5 shows a block diagram 500 of a memory system 520 that supports subblock-dependent word line ramp rates in accordance with examples as disclosed herein. The memory system 520 may be an example of aspects of a memory system as described with reference to FIGS. 1 through 4. The memory system 520, or various components thereof, may be an example of means for performing various aspects of subblock-dependent word line ramp rates as described herein. For example, the memory system 520 may include a control component 525, a driver 530, a selection component 535, or any combination thereof. Each of these components, or components of subcomponents thereof (e.g., one or more processors, one or more memories), may communicate, directly or indirectly, with one another (e.g., via one or more buses).

The control component 525 may be configured as or otherwise support a means for selecting, for writing a first set of data and a second set of data, a block of memory cells that share a word line. The driver 530 may be configured as or otherwise support a means for applying, via the word line as part of a first write operation to write the first set of data, a first voltage pulse having a first ramp rate to a first subblock having a first position within the block. In some examples, the driver 530 may be configured as or otherwise support a means for applying, via the word line as part of a second write operation to write the second set of data, a second voltage pulse having a second ramp rate to a second subblock having a second position within the block.

In some examples, the first ramp rate is faster than the second ramp rate. In some examples, the second position of the second subblock is closer to a center of the block than the first position of the first subblock.

In some examples, the driver 530 may be configured as or otherwise support a means for applying, via the word line as part of a third write operation for a third set of data, a third voltage pulse having a third ramp rate to a third subblock having a third position within the block.

In some examples, the driver 530 may be configured as or otherwise support a means for applying, via the word line as part of a third write operation for a third set of data, a third voltage pulse having the first ramp rate to a third subblock having a third position within the block.

In some examples, the first voltage pulse ramps from a first level to a second level at the first ramp rate. In some examples, the second voltage pulse ramps from the first level to the second level at the second ramp rate.

In some examples, the first voltage pulse ramps from a third level to the first level at third ramp rate before ramping from the first level to the second level. In some examples, the second voltage pulse ramps from the third level to the first level at the third ramp rate before ramping from the first level to the second level.

In some examples, the selection component 535 may be configured as or otherwise support a means for activating a first selection transistor coupled with the word line, where the first voltage pulse is applied to the first subblock based at least in part on activating the first selection transistor. In some examples, the selection component 535 may be configured as or otherwise support a means for activating a second selection transistor coupled with the word line, where the second voltage pulse is applied to the second subblock based at least in part on activating the second selection transistor.

In some examples, the second selection transistor is deactivated as part of the first write operation. In some examples, the first selection transistor is deactivated as part of the second write operation. In some examples, the first write operation and the second write operation include a same type of write operation.

In some examples, the control component 525 may be configured as or otherwise support a means for selecting a first block of memory cells, within a tier of material of a memory device, for writing a first set of data and a second set of data, the first block of memory cells positioned between a first cut through the tier and a second cut through the tier. In some examples, the driver 530 may be configured as or otherwise support a means for applying, via a word line coupled with the memory cells of the first block as part of a first write operation for the first set of data, a first voltage pulse having a first ramp rate to a first subblock of the first block. In some examples, the driver 530 may be configured as or otherwise support a means for applying, via the word line coupled with the memory cells of the first block as part of a second write operation for the second set of data, a second voltage pulse having a second ramp rate to a second subblock of the first block, the second subblock separated from the first subblock by a third cut through the tier.

In some examples, the first block is separated from a second block of the tier by the first cut and is separated from a second block of the tier by the second cut. In some examples, the first ramp rate is faster than the second ramp rate. In some examples, the second subblock is closer to a center of the first block than the first subblock.

In some examples, the driver 530 may be configured as or otherwise support a means for applying, via the word line as part of a third write operation for a third set of data, a third voltage pulse having a third ramp rate to a third subblock separated from the second subblock by a fourth cut through the tier.

In some examples, the driver 530 may be configured as or otherwise support a means for applying, via the word line as part of a third write operation for a third set of data, a third voltage pulse having the first ramp rate to a third subblock separated from the second subblock by a fourth cut through the tier.

In some examples, the first voltage pulse ramps from a first level to a second level at the first ramp rate. In some examples, the second voltage pulse ramps from the first level to the second level at the second ramp rate.

In some examples, the first voltage pulse ramps from a third level to the first level at third ramp rate before ramping from the first level to the second level. In some examples, the second voltage pulse ramps from the third level to the first level at the third ramp rate before ramping from the first level to the second level.

In some examples, the first cut and the second cut are wider than the third cut. In some examples, the material includes an oxide material or a metal material. In some examples, the first write operation and the second write operation include a same type of write operation.

In some examples, the first cut and the second cut are each through a plurality of tiers of the memory device. In some examples, the third cut is through a subset of the plurality of tiers.

In some examples, the described functionality of the memory system 520, or various components thereof, may be supported by or may refer to at least a portion of at least one processor, where such at least one processor may include one or more processing elements (e.g., one or more controllers, one or more microprocessors, one or more microcontrollers, one or more digital signal processors, one or more state machines, discrete gate logic, discrete transistor logic, discrete hardware components, or any combination of one or more of such elements). In some examples, the described functionality of the memory system 520, or various components thereof, may be implemented at least in part by instructions (e.g., stored in memory, non-transitory computer-readable medium) executable by such at least one processor.

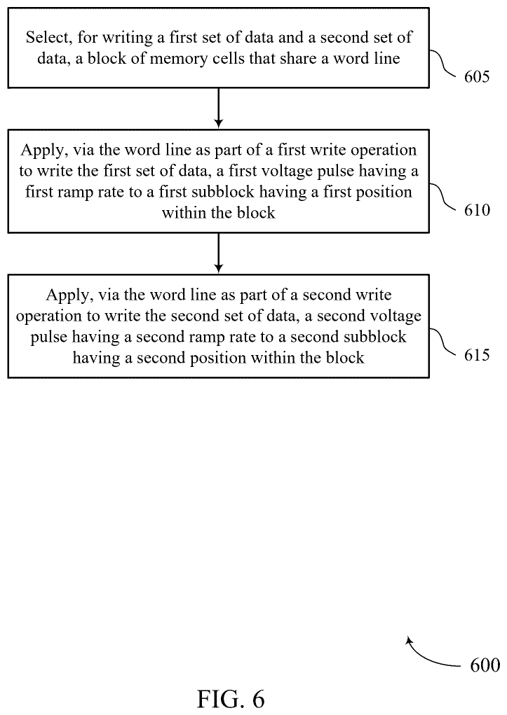

FIG. 6 shows a flowchart illustrating a method 600 that supports subblock-dependent word line ramp rates in accordance with examples as disclosed herein. The operations of method 600 may be implemented by a memory system or its components as described herein. For example, the operations of method 600 may be performed by a memory system as described with reference to FIGS. 1 through 5. In some examples, a memory system may execute a set of instructions to control the functional elements of the device to perform the described functions. Additionally, or alternatively, the memory system may perform aspects of the described functions using special-purpose hardware.

At 605, the method may include selecting, for writing a first set of data and a second set of data, a block of memory cells that share a word line. In some examples, aspects of the operations of 605 may be performed by a control component 525 as described with reference to FIG. 5.

At 610, the method may include applying, via the word line as part of a first write operation to write the first set of data, a first voltage pulse having a first ramp rate to a first subblock having a first position within the block. In some examples, aspects of the operations of 610 may be performed by a driver 530 as described with reference to FIG. 5.

At 615, the method may include applying, via the word line as part of a second write operation to write the second set of data, a second voltage pulse having a second ramp rate to a second subblock having a second position within the block. In some examples, aspects of the operations of 615 may be performed by a driver 530 as described with reference to FIG. 5.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for selecting, for writing a first set of data and a second set of data, a block of memory cells that share a word line; applying, via the word line as part of a first write operation to write the first set of data, a first voltage pulse having a first ramp rate to a first subblock having a first position within the block; and applying, via the word line as part of a second write operation to write the second set of data, a second voltage pulse having a second ramp rate to a second subblock having a second position within the block.

Aspect 2: The method, apparatus, or non-transitory computer-readable medium of aspect 1, where the first ramp rate is faster than the second ramp rate and the second position of the second subblock is closer to a center of the block than the first position of the first subblock.

Aspect 3: The method, apparatus, or non-transitory computer-readable medium of any of aspects 1 through 2, further including operations, features, circuitry, logic, means, or instructions, or any combination thereof for applying, via the word line as part of a third write operation for a third set of data, a third voltage pulse having a third ramp rate to a third subblock having a third position within the block.

Aspect 4: The method, apparatus, or non-transitory computer-readable medium of any of aspects 1 through 3, further including operations, features, circuitry, logic, means, or instructions, or any combination thereof for applying, via the word line as part of a third write operation for a third set of data, a third voltage pulse having the first ramp rate to a third subblock having a third position within the block.

Aspect 5: The method, apparatus, or non-transitory computer-readable medium of any of aspects 1 through 4, where the first voltage pulse ramps from a first level to a second level at the first ramp rate and the second voltage pulse ramps from the first level to the second level at the second ramp rate.

Aspect 6: The method, apparatus, or non-transitory computer-readable medium of aspect 5, where the first voltage pulse ramps from a third level to the first level at third ramp rate before ramping from the first level to the second level and the second voltage pulse ramps from the third level to the first level at the third ramp rate before ramping from the first level to the second level.

Aspect 7: The method, apparatus, or non-transitory computer-readable medium of any of aspects 1 through 6, further including operations, features, circuitry, logic, means, or instructions, or any combination thereof for activating a first selection transistor coupled with the word line, where the first voltage pulse is applied to the first subblock based at least in part on activating the first selection transistor and activating a second selection transistor coupled with the word line, where the second voltage pulse is applied to the second subblock based at least in part on activating the second selection transistor.

Aspect 8: The method, apparatus, or non-transitory computer-readable medium of aspect 7, where the second selection transistor is deactivated as part of the first write operation and the first selection transistor is deactivated as part of the second write operation.

Aspect 9: The method, apparatus, or non-transitory computer-readable medium of any of aspects 1 through 8, where the first write operation and the second write operation include a same type of write operation.

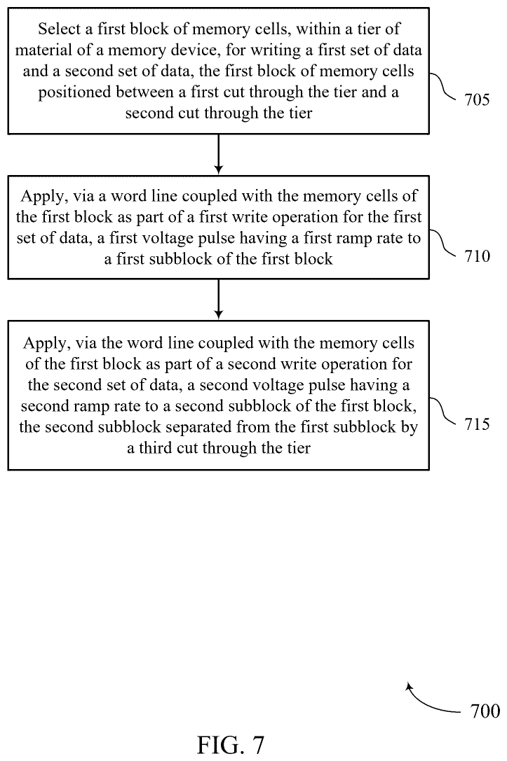

FIG. 7 shows a flowchart illustrating a method 700 that supports subblock-dependent word line ramp rates in accordance with examples as disclosed herein. The operations of method 700 may be implemented by a memory system or its components as described herein. For example, the operations of method 700 may be performed by a memory system as described with reference to FIGS. 1 through 5. In some examples, a memory system may execute a set of instructions to control the functional elements of the device to perform the described functions. Additionally, or alternatively, the memory system may perform aspects of the described functions using special-purpose hardware.

At 705, the method may include selecting a first block of memory cells, within a tier of material of a memory device, for writing a first set of data and a second set of data, the first block of memory cells positioned between a first cut through the tier and a second cut through the tier. In some examples, aspects of the operations of 705 may be performed by a control component 525 as described with reference to FIG. 5.

At 710, the method may include applying, via a word line coupled with the memory cells of the first block as part of a first write operation for the first set of data, a first voltage pulse having a first ramp rate to a first subblock of the first block. In some examples, aspects of the operations of 710 may be performed by a driver 530 as described with reference to FIG. 5.

At 715, the method may include applying, via the word line coupled with the memory cells of the first block as part of a second write operation for the second set of data, a second voltage pulse having a second ramp rate to a second subblock of the first block, the second subblock separated from the first subblock by a third cut through the tier. In some examples, aspects of the operations of 715 may be performed by a driver 530 as described with reference to FIG. 5.

In some examples, an apparatus as described herein may perform a method or methods, such as the method 700. The apparatus may include features, circuitry, logic, means, or instructions (e.g., a non-transitory computer-readable medium storing instructions executable by a processor), or any combination thereof for performing the following aspects of the present disclosure:

Aspect 10: A method, apparatus, or non-transitory computer-readable medium including operations, features, circuitry, logic, means, or instructions, or any combination thereof for selecting a first block of memory cells, within a tier of material of a memory device, for writing a first set of data and a second set of data, the first block of memory cells positioned between a first cut through the tier and a second cut through the tier; applying, via a word line coupled with the memory cells of the first block as part of a first write operation for the first set of data, a first voltage pulse having a first ramp rate to a first subblock of the first block; and applying, via the word line coupled with the memory cells of the first block as part of a second write operation for the second set of data, a second voltage pulse having a second ramp rate to a second subblock of the first block, the second subblock separated from the first subblock by a third cut through the tier.

Aspect 11: The method, apparatus, or non-transitory computer-readable medium of aspect 10, where the first block is separated from a second block of the tier by the first cut and is separated from a second block of the tier by the second cut.

Aspect 12: The method, apparatus, or non-transitory computer-readable medium of any of aspects 10 through 11, where the first ramp rate is faster than the second ramp rate and the second subblock is closer to a center of the first block than the first subblock.

Aspect 13: The method, apparatus, or non-transitory computer-readable medium of any of aspects 10 through 12, further including operations, features, circuitry, logic, means, or instructions, or any combination thereof for applying, via the word line as part of a third write operation for a third set of data, a third voltage pulse having a third ramp rate to a third subblock separated from the second subblock by a fourth cut through the tier.

Aspect 14: The method, apparatus, or non-transitory computer-readable medium of any of aspects 10 through 13, further including operations, features, circuitry, logic, means, or instructions, or any combination thereof for applying, via the word line as part of a third write operation for a third set of data, a third voltage pulse having the first ramp rate to a third subblock separated from the second subblock by a fourth cut through the tier.

Aspect 15: The method, apparatus, or non-transitory computer-readable medium of any of aspects 10 through 14, where the first voltage pulse ramps from a first level to a second level at the first ramp rate and the second voltage pulse ramps from the first level to the second level at the second ramp rate.

Aspect 16: The method, apparatus, or non-transitory computer-readable medium of aspect 15, where the first voltage pulse ramps from a third level to the first level at third ramp rate before ramping from the first level to the second level and the second voltage pulse ramps from the third level to the first level at the third ramp rate before ramping from the first level to the second level.

Aspect 17: The method, apparatus, or non-transitory computer-readable medium of any of aspects 10 through 16, where the first cut and the second cut are wider than the third cut.

Aspect 18: The method, apparatus, or non-transitory computer-readable medium of any of aspects 10 through 17, where the material includes an oxide material or a metal material.

Aspect 19: The method, apparatus, or non-transitory computer-readable medium of any of aspects 10 through 18, where the first write operation and the second write operation include a same type of write operation.

Aspect 20: The method, apparatus, or non-transitory computer-readable medium of any of aspects 10 through 19, where the first cut and the second cut are each through a plurality of tiers of the memory device and the third cut is through a subset of the plurality of tiers.

It should be noted that the described methods include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” “level” or “tier” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials, or combinations thereof. In some examples, one layer or level may be composed of two or more sublayers or sublevels.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively, (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method, comprising:
selecting, for writing a first set of data and a second set of data, a block of memory cells that share a word line;
applying, via the word line as part of a first write operation to write the first set of data, a first voltage pulse having a first ramp rate to a first subblock having a first position within the block; and
applying, via the word line as part of a second write operation to write the second set of data, a second voltage pulse having a second ramp rate to a second subblock having a second position within the block.

2. The method of claim 1, wherein the first ramp rate is faster than the second ramp rate, wherein the second position of the second subblock is closer to a center of the block than the first position of the first subblock.

3. The method of claim 1, further comprising:
applying, via the word line as part of a third write operation for a third set of data, a third voltage pulse having a third ramp rate to a third subblock having a third position within the block.

4. The method of claim 1, further comprising:
applying, via the word line as part of a third write operation for a third set of data, a third voltage pulse having the first ramp rate to a third subblock having a third position within the block.

5. The method of claim 1, wherein the first voltage pulse ramps from a first level to a second level at the first ramp rate, and wherein the second voltage pulse ramps from the first level to the second level at the second ramp rate.

6. The method of claim 5, wherein the first voltage pulse ramps from a third level to the first level at third ramp rate before ramping from the first level to the second level, and wherein the second voltage pulse ramps from the third level to the first level at the third ramp rate before ramping from the first level to the second level.

7. The method of claim 1, further comprising:
activating a first selection transistor coupled with the word line, wherein the first voltage pulse is applied to the first subblock based at least in part on activating the first selection transistor; and
activating a second selection transistor coupled with the word line, wherein the second voltage pulse is applied to the second subblock based at least in part on activating the second selection transistor.

8. The method of claim 7, wherein the second selection transistor is deactivated as part of the first write operation, and wherein the first selection transistor is deactivated as part of the second write operation.

9. The method of claim 1, wherein the first write operation and the second write operation comprise a same type of write operation.

10. A method, comprising:
selecting a first block of memory cells, within a tier of material of a memory device, for writing a first set of data and a second set of data, the first block of memory cells positioned between a first cut through the tier and a second cut through the tier;
applying, via a word line coupled with the memory cells of the first block as part of a first write operation for the first set of data, a first voltage pulse having a first ramp rate to a first subblock of the first block; and
applying, via the word line coupled with the memory cells of the first block as part of a second write operation for the second set of data, a second voltage pulse having a second ramp rate to a second subblock of the first block, the second subblock separated from the first subblock by a third cut through the tier.

11. The method of claim 10, wherein the first block is separated from a second block of the tier by the first cut and is separated from a second block of the tier by the second cut.

12. The method of claim 10, wherein the first ramp rate is faster than the second ramp rate, wherein the second subblock is closer to a center of the first block than the first subblock.

13. The method of claim 10, further comprising:
applying, via the word line as part of a third write operation for a third set of data, a third voltage pulse having a third ramp rate to a third subblock separated from the second subblock by a fourth cut through the tier.

14. The method of claim 10, further comprising:
applying, via the word line as part of a third write operation for a third set of data, a third voltage pulse having the first ramp rate to a third subblock separated from the second subblock by a fourth cut through the tier.

15. The method of claim 10, wherein the first voltage pulse ramps from a first level to a second level at the first ramp rate, and wherein the second voltage pulse ramps from the first level to the second level at the second ramp rate.

16. The method of claim 15, wherein the first voltage pulse ramps from a third level to the first level at third ramp rate before ramping from the first level to the second level, and wherein the second voltage pulse ramps from the third level to the first level at the third ramp rate before ramping from the first level to the second level.

17. The method of claim 10, wherein the first cut and the second cut are wider than the third cut.

18. The method of claim 10, wherein the material comprises an oxide material or a metal material.

19. The method of claim 10, wherein the first write operation and the second write operation comprise a same type of write operation.

20. The method of claim 10, wherein the first cut and the second cut are each through a plurality of tiers of the memory device, and wherein the third cut is through a subset of the plurality of tiers.

21. A memory system, comprising:
one or more memory devices; and
processing circuitry coupled with the one or more memory devices and configured to cause the memory system to:
select, for writing a first set of data and a second set of data, a block of memory cells that share a word line, the block of memory cells included in the one or more memory devices;
apply, via the word line as part of a first write operation to write the first set of data, a first voltage pulse having a first ramp rate to a first subblock having a first position within the block; and
apply, via the word line as part of a second write operation to write the second set of data, a second voltage pulse having a second ramp rate to a second subblock having a second position within the block.

22. The memory system of claim 21, wherein the first ramp rate is faster than the second ramp rate, wherein the second position of the second subblock is closer to a center of the block than the first position of the first subblock.

23. The memory system of claim 21, wherein the processing circuitry is further configured to cause the memory system to:
apply, via the word line as part of a third write operation for a third set of data, a third voltage pulse having a third ramp rate to a third subblock having a third position within the block.

24. The memory system of claim 21, wherein the processing circuitry is further configured to cause the memory system to:
apply, via the word line as part of a third write operation for a third set of data, a third voltage pulse having the first ramp rate to a third subblock having a third position within the block.

25. The memory system of claim 21, wherein the processing circuitry is further configured to cause the memory system to:
activate a first selection transistor coupled with the word line, wherein the first voltage pulse is applied to the first subblock based at least in part on activating the first selection transistor; and
activate a second selection transistor coupled with the word line, wherein the second voltage pulse is applied to the second subblock based at least in part on activating the second selection transistor.

26. A memory system, comprising:
one or more memory devices; and
processing circuitry coupled with the one or more memory devices and configured to cause the memory system to:
select a first block of memory cells, within a tier of material of a memory device, for writing a first set of data and a second set of data, the first block of memory cells positioned between a first cut through the tier and a second cut through the tier;
apply, via a word line coupled with the memory cells of the first block as part of a first write operation for the first set of data, a first voltage pulse having a first ramp rate to a first subblock of the first block; and
apply, via the word line coupled with the memory cells of the first block as part of a second write operation for the second set of data, a second voltage pulse having a second ramp rate to a second subblock of the first block, the second subblock separated from the first subblock by a third cut through the tier.

27. The memory system of claim 26, wherein the processing circuitry is further configured to cause the memory system to:
applying, via the word line as part of a third write operation for a third set of data, a third voltage pulse having a third ramp rate to a third subblock separated from the second subblock by a fourth cut through the tier.

28. The memory system of claim 26, wherein the processing circuitry is further configured to cause the memory system to:
applying, via the word line as part of a third write operation for a third set of data, a third voltage pulse having the first ramp rate to a third subblock separated from the second subblock by a fourth cut through the tier.

29. The memory system of claim 26, wherein the first voltage pulse ramps from a first level to a second level at the first ramp rate, and wherein the second voltage pulse ramps from the first level to the second level at the second ramp rate.
